(19) United States
(12) Patent Application Publication
(10) Pub. No.: US 2026/0342352 A1
(43) Pub. Date: Oct. 29, 2026

(54) DIGITAL-TO-ANALOG CONVERTER, CIRCUIT ARRANGEMENT, DISCRIMINATOR AND PHOTON COUNTING SYSTEM

(71) Applicant: ams International AG, Jona (CH)

(72) Inventors: Fridolin MICHEL, Au (CH); Massimo RIGO, Trieste (IT); Srinidhi Koushik KANAGAL RAMESH, Pfaeffikon (CH)

(21) Appl. No.: 19/118,362

(22) PCT Filed: Sep. 15, 2023
(86) PCT No.: PCT/EP2023/075398

§ 371 Date: Apr. 4, 2025

(30) Foreign Application Priority Data
Oct. 20, 2022 (DE) 10 2022 127 772.0

(51) Int. Cl. H03M 1/66; H03M 1/36; H03M 1/76

(52) U.S. Cl. CPC H03M 1/662; H03M 1/361; H03M 1/76

(57) ABSTRACT

A Digital-to-Analog Converter (100, 100₁, . . . 100ₙ), DAC, comprises a coarse resistor-string digital-to-analog conversion unit (121) for selectively outputting 2^{N}-level analog voltages in response to upper N-bit digital data, wherein N is a natural number greater than or equal to 2, a fine resistor-string digital-to-analog conversion unit (122) for selectively outputting 2^{N}-level analog voltages in response to lower N-bit digital data, and a combining unit (109) for combining an output of the coarse resistor-string digital-to-analog conversion unit (121) and the output of the fine resistor-string digital-to-analog conversion unit (122). The combining unit (109) comprises a capacitor (111). The output of the coarse resistor-string digital-to-analog conversion unit (121) and the output of the fine resistor-string digital-to-analog conversion unit (122) are connectable to a first terminal (137) of the capacitor (111).

### TECHNICAL FIELD

The present disclosure relates to a digital-to-analog voltage converter. The disclosure further relates to a circuit arrangement, a discriminator, a photon counting system and a device for medical diagnostics.

### BACKGROUND

Digital-to-analog converters (DAC) are employed to represent digital values in the analog domain. One category of DACs is represented by resistive DACs, which resort to a matched resistor-string connected between two reference voltages to generate a number of equally spaced intermediate voltages that are selected by an analog multiplexer or switch providing the DAC output. As the analog multiplexer increases in complexity with the number of DAC levels, this type of DAC tends to become area-intensive for resolutions higher than 8 bits.

It is an object of the present invention to provide an improved digital-to-analog converter, an improved circuit arrangement, an improved discriminator, an improved photon counting system, and an improved device for medical diagnostics.

### SUMMARY

According to embodiments, the above object is achieved by the claimed matter according to the independent claims. Advantageous further developments are defined in the dependent claims.

A Digital-to-Analog Converter, DAC, comprises a coarse resistor-string digital-to-analog conversion unit for selectively outputting 2^{N}-level analog voltages in response to upper N-bit digital data, wherein N is a natural number greater than or equal to 2 and a fine resistor-string digital-to-analog conversion unit for selectively outputting 2^{N}-level analog voltages in response to lower N-bit digital data. The DAC further comprises a combining unit for combining an output of the coarse resistor-string digital-to-analog conversion unit and the output of the fine resistor-string digital-to-analog conversion unit. The combining unit comprises capacitor. The output of the coarse resistor-string digital-to-analog conversion unit and the output of the fine resistor-string digital-to-analog conversion unit are connectable to a first terminal of the capacitor.

According to embodiments, the coarse resistor-string digital-to-analog conversion unit comprises a coarse resistor-string and a coarse multiplexer which is configured to be connected to a selected tap between resistors of the coarse resistor-string. Further, the fine resistor-string digital-to-analog conversion unit may comprise a fine resistor-string and a fine multiplexer which is configured to be selectively connected to a selected tap between resistors of the fine resistor-string. The coarse resistor-string and the fine resistor-string may be connected in series.

The DAC may further comprise a first buffer receiving a reference voltage and controlling a voltage supplied to the coarse resistor-string.

According to embodiments, the first buffer comprises a first buffer capacitor for storing an offset voltage. The first buffer may further comprise a second buffer capacitor for storing a reference voltage.

For example, the first buffer may comprise a first buffer circuit and a second buffer circuit, each of the first and the second buffer circuits comprising a first buffer capacitor, respectively. The first buffer circuit and the second buffer circuit may be configured to be alternatingly operated.

According to embodiments, the coarse resistor-string digital-to-analog conversion unit further comprises a high-ohmic coarse resistor-string which is connected in parallel to the coarse resistor-string, a resistance of the high-ohmic coarse resistor-string being greater than the resistance of the coarse resistor-string. The high-ohmic coarse resistor-string is configured to be connected to the coarse multiplexer when the coarse multiplexer is connected to the first terminal of the capacitor.

Moreover, the fine resistor-string digital-to-analog conversion unit may further Comprise a low-ohmic fine resistor-string which is connected in parallel to the fine resistor-string, a resistance of the low-ohmic fine resistor-string being less than the resistance of the fine resistor-string. The low-ohmic fine resistor-string is configured to be connected to the fine multiplexer when the fine multiplexer is connected to the first terminal of the capacitor.

According to embodiments, the DAC may further comprise an additional switchable resistor-string between the coarse resistor-string and the fine resistor-string.

According to further embodiments, a circuit arrangement comprises a digital-to-analog converter, DAC, and a comparator. The DAC comprises a coarse resistor-string digital-to-analog conversion unit for selectively outputting 2^{N}-level analog voltages in response to upper N-bit digital data, wherein N is a natural number greater than or equal to 2, a fine resistor-string digital-to-analog conversion unit for selectively outputting 2^{N}-level analog voltages in response to lower N-bit digital data, and a combining unit for combining an output of the coarse resistor-string digital-to-analog conversion unit and the output of the fine resistor-string digital-to-analog conversion unit. The combining unit comprises a capacitor. The output of the fine resistor-string digital-to-analog conversion unit is connectable to a first terminal of the capacitor, and a second terminal of the capacitor being connectable to a first input of the comparator.

For example, the output of the coarse resistor-string digital-to-analog conversion unit is connectable to a second input of the comparator.

According to embodiments, the output of the coarse resistor-string digital-to-analog conversion unit is connectable to a frontend circuit. The frontend circuit is configured to receive an input signal and to supply a processed signal to a second input of the comparator. The processed signal is generated on the basis of the input signal and the output of the coarse resistor-string digital-to-analog conversion unit.

For example, the output of the coarse resistor-string digital-to-analog conversion unit may be V/I converted before being supplied to the frontend circuit.

According to embodiments, the output of the coarse resistor-string digital-to-analog conversion unit is connectable to the first terminal of the capacitor. The circuit arrangement may further comprise a frontend circuit which is configured to receive an input signal and to supply a processed signal to a second input of the comparator. The frontend circuit may be permanently connected to the second input of the comparator. The processed signal may be based on the input signal and the output of the coarse resistor-string digital-to-analog conversion unit.

According to further embodiments, a discriminator comprises a plurality of discriminator stages. Each of the discriminator stages comprises a comparator, a coarse multiplexer and a fine multiplexer. The coarse multiplexer being connectable to a selected tap connecting resistors of a coarse resistor-string for selectively outputting 2^{N}-level analog voltages in response to upper N-bit digital data, wherein N is a natural number greater than or equal to 2. The fine multiplexer is connectable to a selected tap connecting resistors of a fine resistor-string for selectively outputting 2^{N}-level analog voltages in response to lower N-bit digital data. The discriminator stage further comprises a combining unit for combining an output of the coarse multiplexer and the output of the fine multiplexer. The combining unit comprises a capacitor. The output of the fine multiplexer is connectable to a first terminal of the capacitor, and a second terminal of the capacitor is connectable to a first input of the comparator.

For example, the output of the coarse multiplexer is connectable to a second input of the comparator.

Further, the output of the coarse multiplexer may be connectable to a frontend circuit configured to receive an input signal and to supply a processed signal to a second input of the comparator, the processed signal being based on the input signal and the output of the coarse multiplexer.

According to embodiments, a photon counting system comprises the discriminator as defined above. A device for medical diagnostics may comprise the photon counting system.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 shows a schematic view of a photon counting system.

FIGS. 2A and 2B illustrate embodiments of DACs forming part of discriminator stages, respectively.

FIGS. 3A to 3E illustrate examples of circuit arrangements forming part of discriminator stages, respectively.

FIGS. 4A to 4C illustrate further examples of DACs forming part of discriminator stages, respectively.

FIGS. 5A and 5B illustrate examples of DACs forming part of discriminator stages, respectively.

FIG. 6 shows an example of a further photon counting system.

FIG. 7 illustrates a device for medical diagnostics.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As employed in this specification, the terms “coupled” and/or “electrically coupled” are not meant to mean that the elements must be directly coupled together-intervening elements may be provided between the “coupled” or “electrically coupled” elements. The “electrically connected” intends to describe a low-ohmic electric connection between the elements electrically connected together. According to further embodiments and where appropriate, the term “electrically connected” may mean that the respective elements are “directly connected” or are “directly and permanently connected”.

The term “component A is permanently connected to component B” is intended to mean that there is a direct connection between component A and component B without a switch. When any of components A or B is disconnected from a power supply or an input signal, this feature still is satisfied when a connection, e.g. a corresponding wiring is connected to component A and component B.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

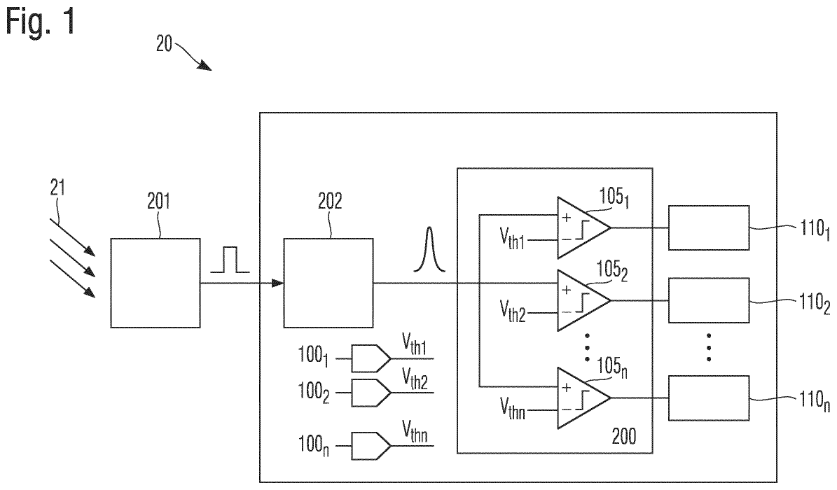

FIG. 1 shows a schematic view of a photon counting system 20, which may comprise a digital-to-analog converter 100 that will be explained herein below. In the photon counting system 20 illustrated in FIG. 1, single photon events 21 are detected and counted in order to obtain intensity in spectral information. Whereas in a classical image or X-ray sensor only the total input intensity is measured, in a photon counting system as illustrated in FIG. 1, the photons 21 are detected individually. Accordingly, the photon energy may be extracted. The photon counting system illustrated in FIG. 1, comprises a photon detector 201 that may comprise a special sensor material which converts photons into current pulses. These current pulses are converted to voltage pulses by a frontend circuit 202, e.g. a CMOS frontend circuit. Signals are generated, wherein the height of the output voltage peak is related to the photon energy, thus containing spectral information. Digitization of the spectral information (i.e. the height of the output pulse) may be performed using a discriminator 200 which comprises a plurality of comparators 105₁, 105₂, . . . 105ₙ. Different threshold voltages Vth₁, Vth₂, . . . Vthₙ are supplied to the different comparators. By counting the individual discriminator outputs, the spectral distribution of the photon events may be determined.

For high performance photon counting, the comparator thresholds in the discriminator 200 need to be defined with high resolution. Typically, hundreds of channels are integrated on a single die and each channel comprises an array of DACs. Accordingly, there is a need for implementing each DAC with minimum area as possible.

The different threshold voltages are supplied by different DACs 100₁, 100₂, . . . 100ₙ. For example, the DACs may provide non-equally spaced threshold voltages for comparators. Due to a comparable large time between the different photon events, a refreshing of the threshold voltages is necessary. Therefore, digital-to-analog conversion has to be continuously performed.

As is illustrated in FIG. 1, a discriminator 200 comprises a multitude of DACs. Usually, clusters of DACs are implemented which are based on a shared architecture. In more detail, concepts are being developed according to which part of the circuits may be shared among the different DACs. In particular, a discriminator 200 may comprise a plurality of discriminator stages 210ᵢ. Each of the discriminators stages 210ᵢ comprises a comparator 105 and elements of a DAC 100ᵢ associated to the discriminator stage 210ᵢ. Further elements of the DAC are shared among the single discriminator stages 210ᵢ.

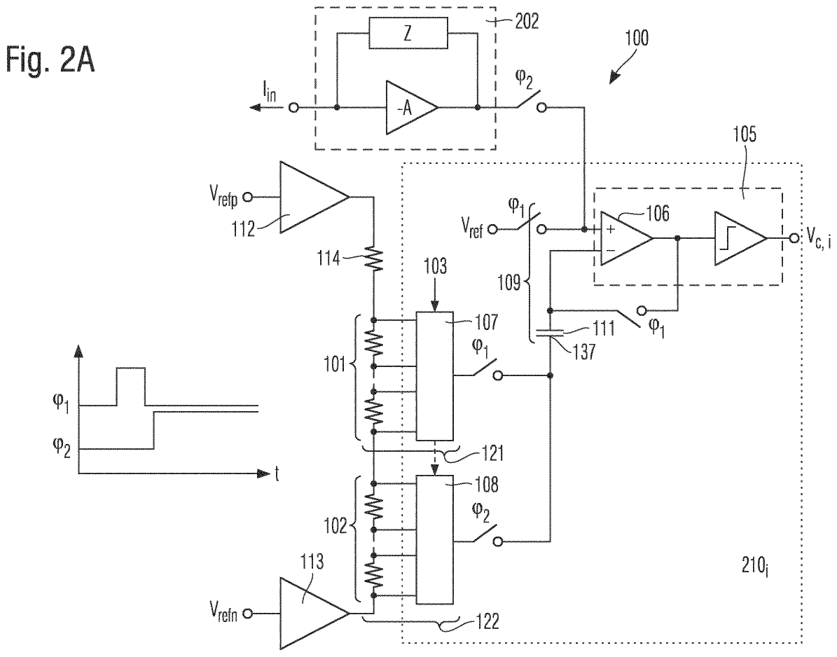

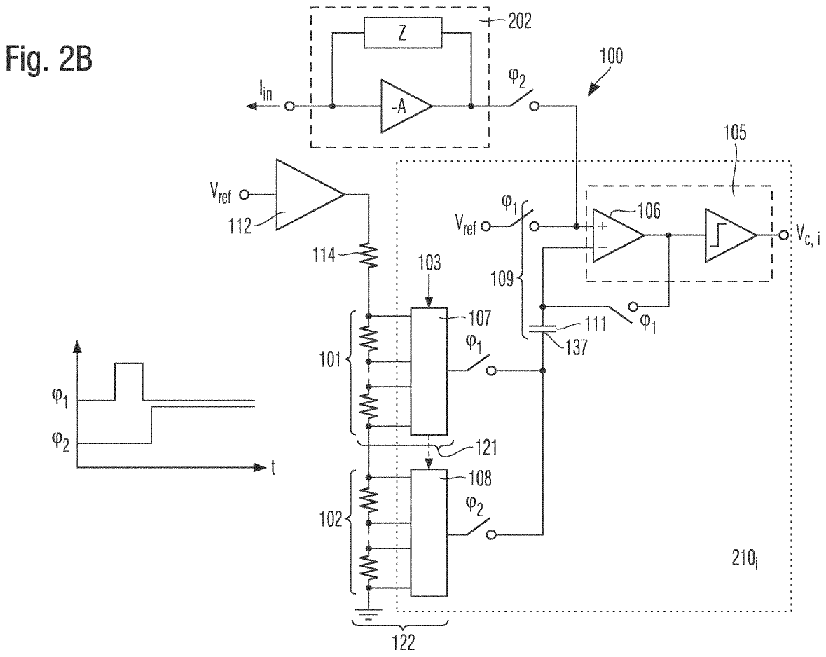

FIG. 2A shows an example of a DAC 100 according to embodiments. The DAC 100 is a component of a discriminator stage 210ᵢ forming a component of the discriminator 200.

The DAC 100 comprises a coarse resistor-string digital-to-analog conversion unit 121 for selectively outputting 2^{N}-level analog voltages in response to upper N-bit digital data, wherein N is a natural number greater than or equal to 2. The DAC 100 further comprises a fine resistor-string digital-to-analog conversion unit 122 for selectively outputting 2^{N}-level analog voltages in response to lower N-bit digital data. The DAC 100 further comprises a combining unit 109 for combining an output of the coarse resistor-string digital-to-analog conversion unit 121 and the output of the fine resistors-string digital-to-analog conversion unit 122. The combining unit 109 comprises a capacitor 111.

According to embodiments illustrated in FIG. 2A, the output of the coarse resistor-string digital-to-analog conversion unit 121 and the output of the fine resistor-string digital-to-analog conversion unit 122 are connectable to a first terminal 137 of the capacitor 111. As will be explained in the following, due to the presence of the capacitor 111, which combines the output of the coarse resistor-string digital-to-analog conversion unit 121 and the output of the fine resistor-string digital-to-analog conversion unit 122, a second buffer stage may be dispensed with. Hence, area may be reduced.

The coarse resistor-string digital-to-analog conversion unit 121 may comprise a coarse resistor-string 101 and a coarse multiplexer 107. The fine resistor-string digital-to-analog conversion unit 122 may comprise a fine resistor-string and a fine multiplexer 108.

The DAC illustrated in FIG. 2A comprises a first buffer 112 which receives a first reference voltage (Vrefp) as an input. The first reference voltage (Vrefp) may be a positive voltage. The buffer 112 is connected to a coarse resistor-string 101. The term “resistor-string” is used herein to refer to one or more resistors connected in series. The coarse resistor-string 101 comprises a plurality of resistors and operates as a coarse resistor-string. The terms “coarse” and “fine” referred to herein in relation to a resistor-string refer to the voltage step, or resolution, across each resistors of the resistor-string and not to their resistive value. The plurality of resistors in the coarse resistor-string 101 may be of equal resistance value so that the potential difference is divided across the resistors of the coarse resistor-string 101 in equal steps. Likewise, the resistors of the fine resistor-string 102 may have equal resistance values so that the potential difference is divided across the fine resistor-string 102 in equal steps. According to further embodiments, any of the transistors may have different resistance values so that a potential difference is divided in non-linear steps. The fine resistor-string 102 covers only one coarse level. Accordingly, the fine voltage steps are used to interpolate consecutive levels of the coarse resistor-string 101.

A second buffer 113 receives a second reference voltage (Vrefn) which is lower than the first reference voltage (Vrefp). The fine resistor-string 102 is connected to the second buffer 113A.

The coarse multiplexer 107 may be implemented as a coarse switch tree. For example, the coarse resistor-string may comprise a plurality of voltage taps (a contact that may be reached by the coarse multiplexer 107) and the coarse multiplexer 107 comprises a plurality of switches. Each of the plurality of switches of the coarse multiplexer 107 are controllable to connect to one of the voltage taps of the coarse resistor-string 101. The fine resistor-string and the fine multiplexer 108 may be implemented in a corresponding manner.

When a bit string 103 is input to the DAC 100, e.g. to the coarse multiplexer 107, the switches of the coarse multiplexer 107 are activated in accordance with the upper bits, e.g. the upper N-bit digital data. Further, the switches of the fine multiplexer 108 are activated in accordance with the lower N-bit digital data. Accordingly, the coarse resistor-string digital-to-analog conversion unit 121 selectively outputs 2^{N}-level analog voltages in response to upper N-bit digital data, and the fine resistor-string digital-to-analog conversion unit 122 selectively outputs 2^{N}-level analog voltages in response to lower N-bit digital data.

As is further shown in FIG. 2A, the fine resistor-string 102 and the coarse resistor-string 101 are shared among a plurality of discriminator stages 210ᵢ.

The discriminator stage 210ᵢ further comprises a comparator 105. The comparator 105 comprises a pre-amplifier 106. The comparator 105 outputs a comparator voltage V_{c,I} for the respective discriminator stage 210ᵢ. The comparator voltage V_{c,I} depends on a result of comparison of a voltage input by a frontend circuit 202 with the analog threshold voltage Vth.

The frontend circuit 202, e.g. a CMOS frontend circuit receives a current signal from the detector 201. The frontend circuit 202 may comprise a charge sensitive amplifier. For example, the inverting input of the charge sensitive amplifier may receive the current signal Iᵢₙ. A feedback resistor may be connected between the inverting input of the charge sensitive amplifier and the output of the charge sensitive amplifier. The frontend circuit 202 may comprise a shaping amplifier stage (not shown), configured to receive the output of the charge sensitive amplifier and to output a voltage signal comprising bell-shaped pulses.

As is further shown in FIG. 2A, a first input of the comparator 105 or the pre-amplifier 106 is connected to a reference voltage Vref during a phase φ₁. During a phase φ₂, the first input of the comparator 105 or the pre-amplifier 106 is connected to the frontend circuit 202. During phase φ₁, the output of the pre-amplifier 106 is fed back to a second input of the pre-amplifier 106. The discriminator stage 210ᵢ or DAC 100 comprises a capacitor 111. For example, the first input may be a non-inverting input of the comparator, and the second input may be an inverting input of the comparator. As will be explained in the following, due to this configuration, the pre-amplifier 106 may be offset compensated in an auto zero loop where the offset is stored on the capacitor 111. Generally, depending on a polarity of a signal output by the shaping amplifier stage, the first input may be a non-inverting or an inverting input.

FIG. 2A shows in the insert a time diagram of the different phases φ₁ and φ₂ for operating the discriminator stage 210ᵢ. During the first phase φ₁, the coarse voltage is sampled. The coarse voltage is selected by the coarse multiplexer 107. The selected coarse voltage is sampled on the capacitor 111 with respect to a reference voltage. As a result, the difference between the comparator offset voltage and the coarse DAC voltage is stored on the capacitor 111. Hence, complexity and capacitor area are reduced.

In a photon counting system comprising a plurality of discriminator stages 210ᵢ, several different coarse voltages may be sampled in parallel by connecting several independent coarse multiplexers 107 to the coarse resistor-string 101. This allows the generation of a cluster of DACs which are required for the discriminator 200 without increase in static power consumption. Consequently, this topology is highly scalable. The fine voltage is added during the second phase φ₂, i.e. the active photon counting phase. The fine voltages for each DAC 100 in the cluster are selected by independent multiplexers 108 and are connected in series with the respective capacitors 111 holding the coarse voltages and comparator offset voltage. Accordingly, an output voltage Vth,comp output by the pre-amplifier 106 in phase φ₂ is given as:

Vth,comp=Vref−Vcoarse+Vfine.

The reference voltages which are applied to the coarse string 101 and the fine string 102 need not be the same. In most practical cases, they may be the same. In this case, the DAC range may be adjusted by moving the coarse voltage with respect to Vref by introducing a voltage drop via the resistor 114 on top of the coarse resistor-string 101.

Due to the configuration described above, in particular, since the combining unit 109 comprises a capacitor 111, area of the DAC may be reduced. Further, due to the presence of the capacitor 111, the offset voltage may be compensated.

FIG. 2B shows a further example of a DAC 100 forming part of a discriminator stage 2101. Embodiments illustrated in FIG. 2B are identical with components of FIG. 2A. Differing from embodiments illustrated in FIG. 2A, the second buffer 113 is replaced by a low-ohmic ground connection. Accordingly, the fine resistor-string 102 is connected to ground. As a result, area and power may further be reduced.

As has been explained above, according to embodiments that are illustrated in FIGS. 2A and 2B, a combination of the coarse voltage and the fine voltage is achieved during phase φ₂.

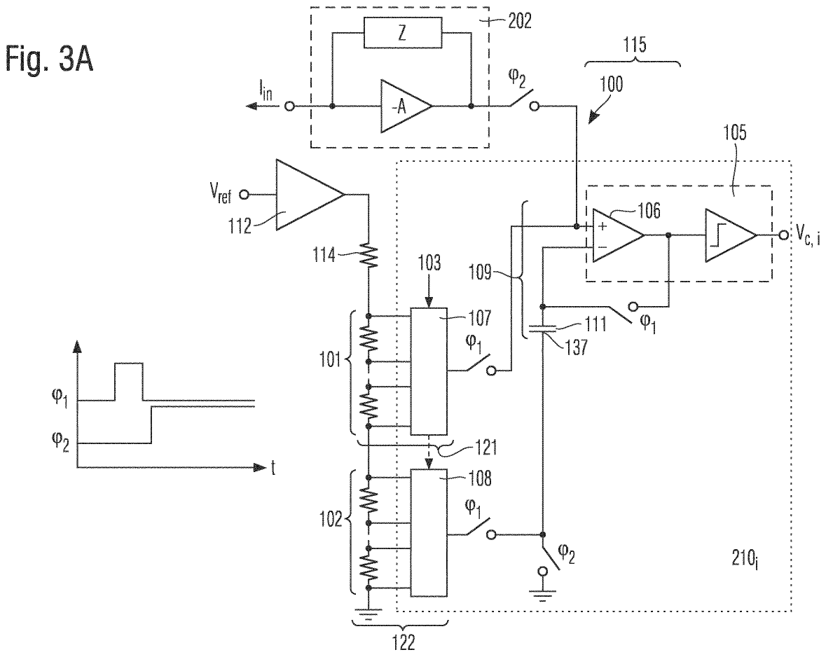

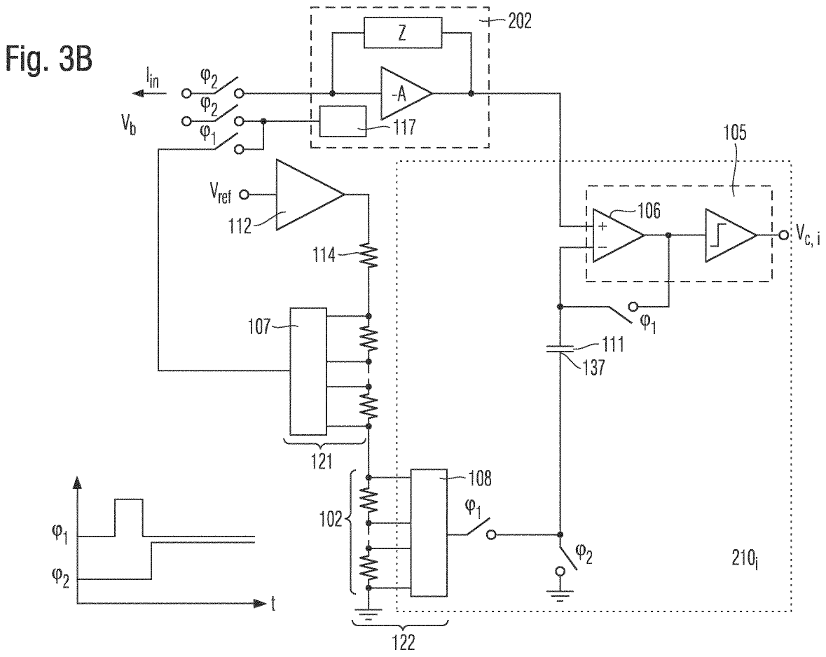

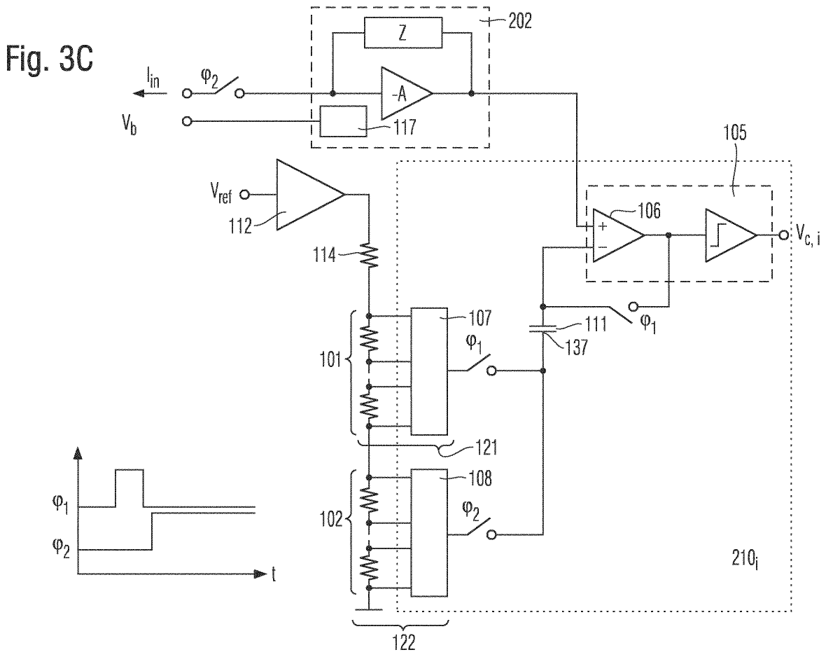

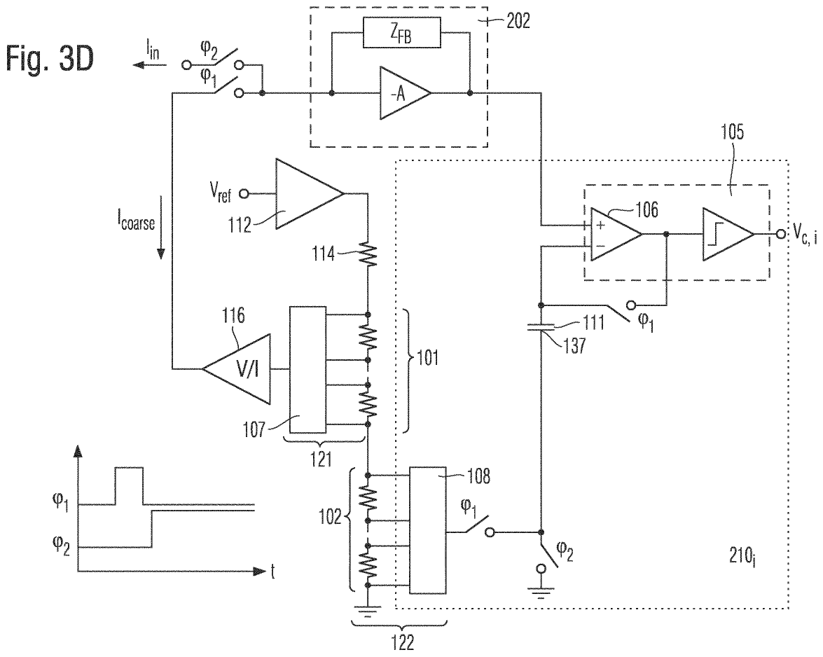

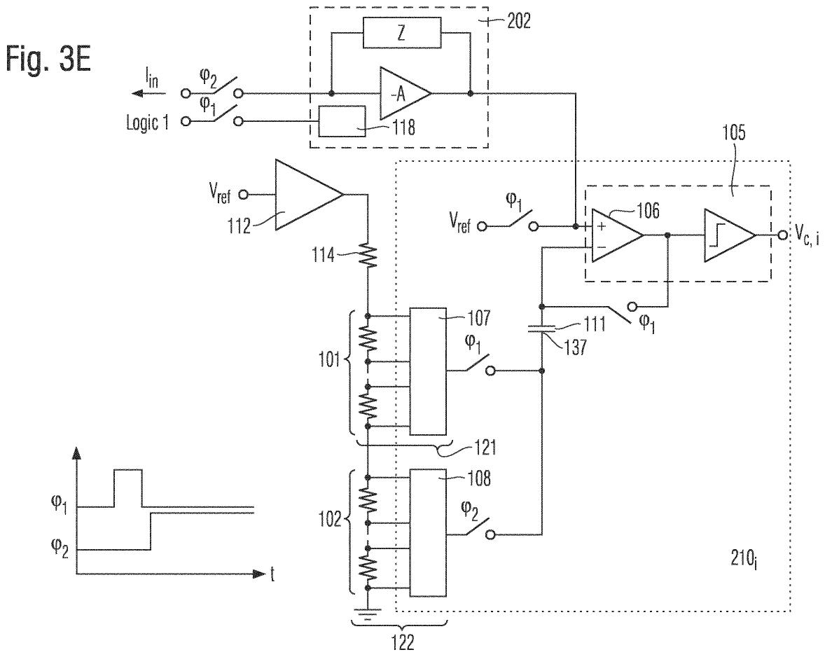

FIG. 3A shows a circuit arrangement 115 and further a corresponding discriminator stage 210₁ which employs a different switching scheme. In particular, as is shown, instead of connecting a reference voltage to the non-inverting input of the pre-amplifier 106, the coarse voltage is applied to the non-inverting input of the pre-amplifier 106 during phase φ₁. Further, during phase φ₁, the fine voltage is applied to the first terminal 137 of the capacitor 111. During phase φ₁ the output of the pre-amplifier 106 is input to the inverting input of the pre-amplifier 106. During the photon counting phase φ₂, the fine multiplexer 108 is no longer connected to the capacitor 111. Instead, the first terminal 137 of the capacitor 111 is pulled to ground or a reference voltage. Hence, the DAC is no longer needed during the counting phase φ₂ and may be powered down. As a result, power may be saved.

The switching scheme results in an effective comparator threshold voltage of

Vth,comp=Vcoarse−V_{fine}.

Accordingly, FIG. 3A shows a circuit arrangement 115 comprising a digital-to-analog converter DAC 100 and a comparator 105. The DAC comprises a coarse resistor-string digital-to-analog conversion unit 121 for selectively outputting 2^{N}-level analog voltages in response to upper N-bit digital data, wherein N is a natural number greater than or equal to 2, and a fine resistor-string digital-to-analog conversion unit 122 for selectively outputting 2^{N}-level analog voltages in response to lower n-bit digital data. The DAC further comprises a combining unit for combining the output of the coarse resistor-string digital-to-analog conversion unit 121 and the output of the fine resistor-string digital-to-analog conversion unit 122. The combining unit 109 comprises a capacitor 111. The output of the fine resistor-string digital-to-analog conversion unit is connectable to a first terminal of the capacitor 111. A first terminal 137 of the capacitor 111 is connectable to a first input of the comparator 105.

As has been explained above, according to embodiments, that are illustrated in FIGS. 2A, 2B and 3A, the frontend circuit 202 is connected via a switch 104 to the discriminator stage 210ᵢ in phase φ₂. This switch 104 forms an RC filter in combination with the comparator parasitic input capacitances. This may cause considerable distortion and speed limitations when operating at a low supply voltage with low overdrive for a MOS transistor switch 104. For this reason, according to further implementations, the frontend circuit 202 may be directly and permanently connected to all the comparators 105 in the respective discriminator stages 210ᵢ.

This is further explained with reference to FIGS. 3B and 3C. When employing this arrangement, it may be impossible to apply individual coarse voltages for the comparators in the discriminator stage 210ᵢ during phase φ₁. Hence, the comparators 105 may be offset-compensated one at a time. Alternatively, the scheme illustrated in FIG. 2A or 2B may be used where the coarse voltage is applied to the capacitor 111 during phase φ₁ and the fine voltage is added during the counting phase φ₂.

According to an implementation, which is shown in FIG. 3B, the frontend circuit 202 may be directly and permanently connected to the respective comparators 105. Further, during phase φ₁ the coarse voltage is applied to a baseline control circuit for controlling a baseline of signals output via the frontend circuit 202. During phase φ₂ a reference voltage V_{b} is applied to the baseline control circuit. This reference voltage or baseline voltage corresponds to a target voltage for the baseline. The signal input serves as a reference for the baseline control circuit. Hence, in this case, the frontend circuit 202 or the shaping circuit may act as a buffer driving the comparators with a voltage proportional to the applied coarse or baseline reference voltage. The signal input to the frontend circuit 202 may be disconnected in phase φ₁ in order to guarantee an undisturbed output of the frontend circuit 202.

As is further shown in FIG. 3B, according to this implementation, the coarse multiplexer 107 is shared among the different stages. Accordingly, the different comparators of the discriminator 210 are not calibrated in parallel but only one at a time (per frame).

According to the implementation shown in FIG. 3B, since the fine multiplexer 108 is connected to the first terminal 137 of the capacitor 111 and the coarse multiplexer 107 is not connected to the capacitor, the fine voltage may be re-subtracted.

FIG. 3C shows a configuration, in which an output of the coarse multiplexer 107 is connected to the first terminal 137 of the capacitor 111 during phase φ₁. The output of the fine multiplexer 108 is connected to the first terminal 137 of the capacitor during phase φ₂.

According to embodiments illustrated in FIG. 3D, the circuit arrangement 115 further comprises a voltage-current-converter 116 that is arranged between the coarse multiplexer 107 and the frontend circuit 202. The output of the coarse multiplexer 107 is converted into a current by a voltage-current converter 116 and fed to the frontend circuit 202 via a switch. Accordingly, the coarse voltage signal is injected into the frontend circuit 202 as a current signal. The frontend circuit 202 multiplies this coarse current with its transimpedance ZFB, providing a voltage output proportional to V_{coarse}.

FIG. 3E shows a further embodiment of the circuit arrangement 115, in which the frontend circuit 202 has a control input to set its output into a high impedance state by a control circuit 118 (HZ block). As a result, the voltage may be directly overwritten at the input of the preamplifier 106 with a reference voltage during phase φ₁. The input to the control circuit 118 is a digital control signal (logic 1).

According to further concepts, the first buffer 112 may be offset compensated so as to eliminate the impact of buffer offset.

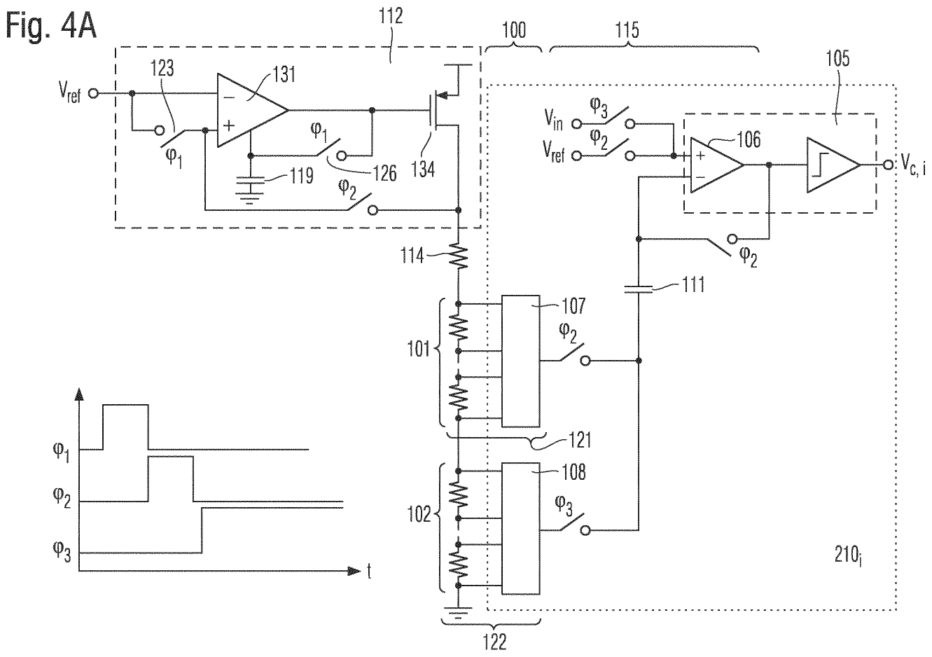

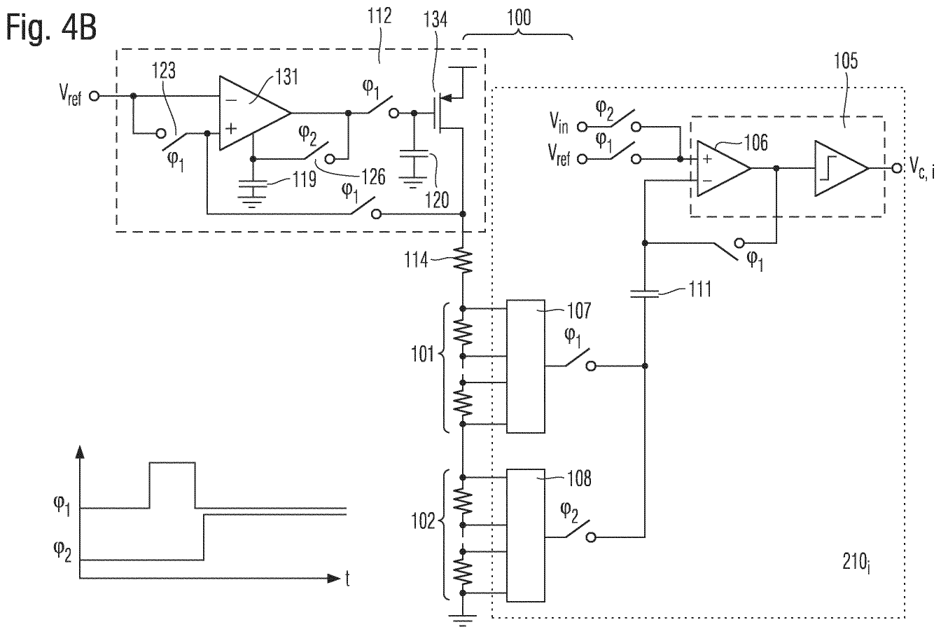

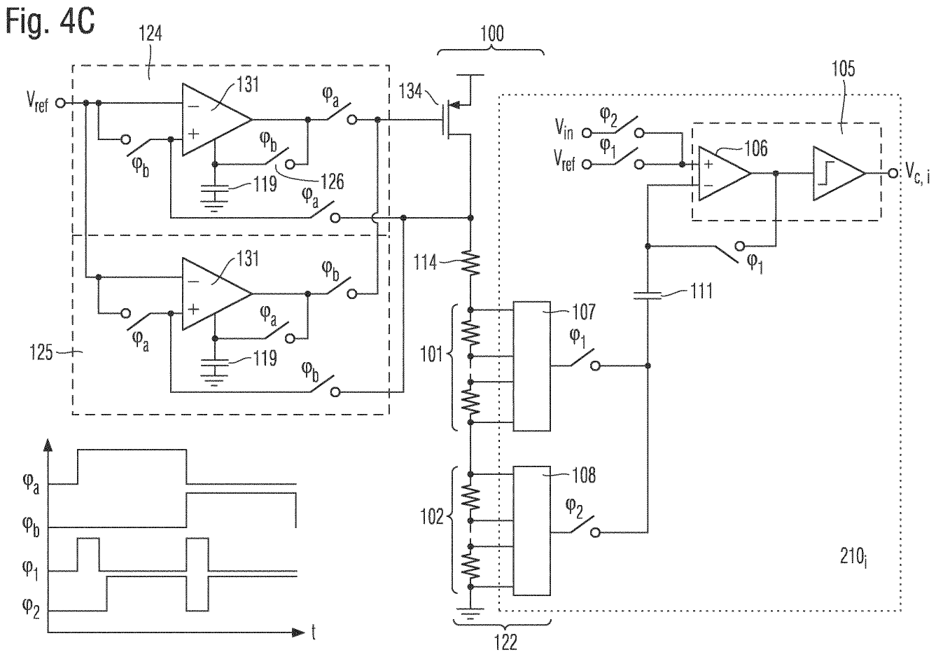

FIG. 4A shows an example of a DAC 100 which may form part of a discriminator stage 210ᵢ. The DAC 100 may be implemented in any of the manners as discussed above. Further, the first buffer 112 may be modified so as to be offset compensated. In more detail, the buffer 112 may be implemented as a circuit comprising an amplifier 131 and a first buffer capacitor 119.

Vref is applied to the inverting input of the amplifier 131. Vref is applied to the non-inverting input of the amplifier 131 via a switch 123 which is closed during phase φ₁. The first buffer capacitor 119 is arranged between an auxiliary input of the amplifier 131 and a ground terminal. An output of the amplifier 131 is fed back to the auxiliary input of the amplifier 131 via a switch 126 that is closed during phase φ₁.

During phase φ₁, the switches 123 and 126 are closed. Vref is applied to the inverting and to the non-inverting input of the amplifier 131. Hence, the first buffer capacitor 119 is charged with charges corresponding to the offset voltage of the amplifier 131. During phase φ₂, which corresponds to phase φ₁ as e.g. described with reference to FIG. 2A, the switches 123 and 126 are open. In this phase, the output of the amplifier 131 is offset compensated due to the charges stored in the first buffer capacitor 119. The output of amplifier 131 is connected to the gate electrode of transistor 134 which may be a P-MOSFET. The voltage supplied to the coarse and the fine resistor-strings 101 and 102 is forced to Vref. The voltage output of the coarse multiplexer 107 is stored on the capacitor 111.

During phase φ₃ which refers to a photon counting phase, the same processes as described above with reference to FIG. 2A are performed. In the diagram of FIG. 4A, the output of the frontend circuit 202 is denoted as Vᵢₙ. A description of the frontend circuit 202 is omitted from this figure.

FIG. 4B shows a further example of a DAC 100 wherein the circuit implementing the first buffer 112 further comprises a second buffer capacitor 120. The second buffer capacitor 120 is connected to a node between the amplifier 131 and the gate electrode of the transistor 134. The circuit implementing the first the buffer 112 is further modified. Due to the presence of the second buffer capacitor 120, the DAC 100 may be operated in two phases instead of three phases. Accordingly, in order to reduce the number of phases, offset compensation of the first buffer 112 may be performed during the DAC operation phase φ₂. In order to keep the coarse tree operational, the buffer output voltage is stored on the second buffer capacitor 120 to properly bias the transistor 134 current source during phase φ₂. Depending on the length of phase φ₂, leakage may cause significant droop in the coarse tree current. Further, the large second capacitor 120 connected to the buffer output may complicate frequency compensation.

FIG. 4C shows a further implementation of the first buffer 112 in which droop due to capacitor leakage may be avoided. According to the configuration illustrated in FIG. 4C the second buffer capacitor 120 is replaced by a second buffer circuit 125. Accordingly, as is illustrated in FIG. 4C, the DAC comprises a first buffer circuit 124 and a second buffer circuit 125. Each of the first and second buffer circuits 124, 125 comprises an amplifier and a first buffer capacitor 119. The respective switches are configured to be driven at complementary phases. Accordingly, only one buffer is connected to the coarse tree at a time while the other buffer is offset compensated. Accordingly, the combination of the first and the second buffer circuits implements a ping-pong buffer. Periodic swapping of the buffers results in refreshing of the buffer out of zero state. Accordingly, the DAC 100 illustrated in FIG. 4C may be operated faster.

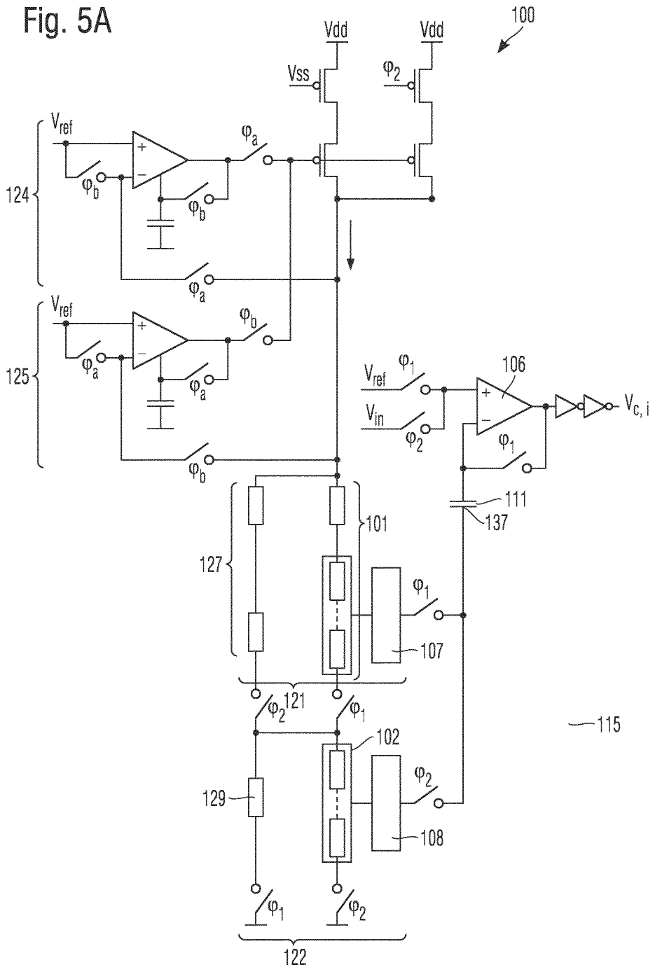

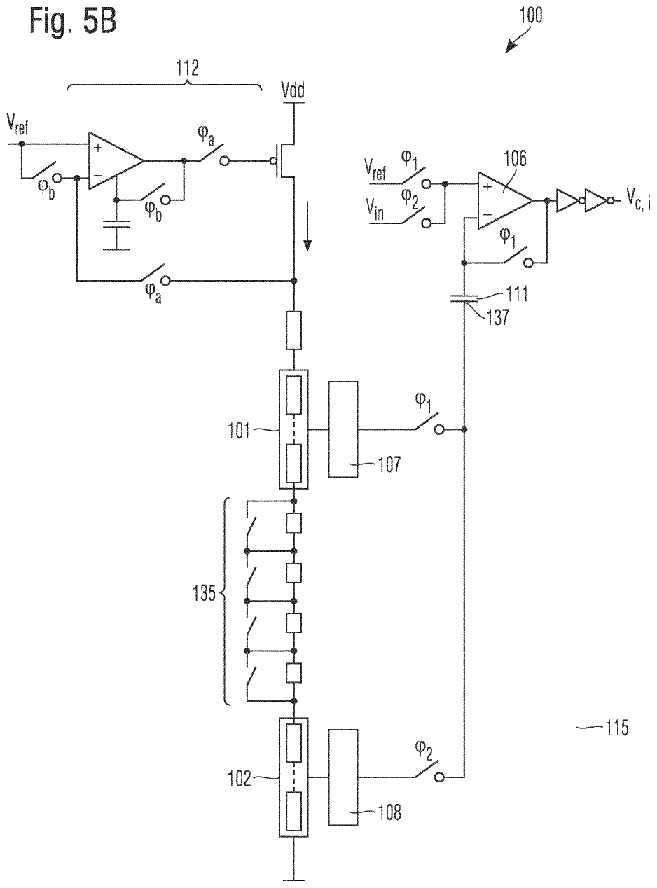

FIG. 5A illustrates a further embodiment of a DAC 100 wherein the coarse and the fine resistor-strings 101, 102 may be implemented in an alternative way. The further components of the DAC may be similar to the one illustrated in e.g. FIG. 2A. Moreover, the DAC may further comprise a first buffer circuit 124 and a second buffer circuit 125 which has been e.g. explained with reference to FIG. 4C. As is to be clearly understood, the voltage supply of the coarse and the fine resistor-strings 101, 102 may be implemented in any arbitrary manner.

Differing from embodiments disclosed with reference to FIG. 4C, for example, a variable resistance string is introduced for the coarse resistor-string 101 and the fine resistor-string 102. Thereby, the average current consumption may be further reduced.

Typically, the coarse resistor-string 101 is implemented with a larger number of taps compared to the fine string, for matching purposes. Also, the fine resistor-string 102 covers a small range, typically equal or larger than the coarse string resolution. As a consequence, the fine string has a smaller resistance compared to the coarse string, making the dynamic settling in phase φ₂ faster than the one in phase φ₁. Since during phase φ₁ the capacitor 111 is charged, while during phase φ₂, only parasitic capacitances are charged, this effect is enhanced. As a consequence, during phase φ₂, settling is mostly limited by parasitic capacitances and the speed of the reference buffer. Considering the DAC illustrated in FIG. 4C, e.g. the string current is primarily dictated by the settling requirements of the RC circuit, comprising a coarse resistor-string 101, the coarse multiplexer 107, the capacitor 111 and the pre-amplifier 106 speed and significantly less by the dynamic of the resistor fine string 102.

As is shown in FIG. 5A, a low-ohmic fine resistor-string 129 may be added in parallel to a high-ohmic fine resistor-string 102. The high-ohmic fine resistor-string 102 has a larger resistance than the fine resistor-string 102 described herein before, e.g. with reference to FIG. 4C.

Further, a high-ohmic coarse resistor-string 127 may be added in parallel to a low-ohmic coarse resistor-string 101. The low-ohmic coarse resistor-string 101 has a smaller resistance than the coarse resistor-string 101 described hereinbefore, e.g. with reference to FIG. 4C.

During phase φ₁, when the fine multiplexer 108 is not connected to the capacitor 111, settling is important. During phase φ₁, a low ohmic resistor-string is needed. Accordingly, the parallel low-ohmic fine resistor-string 129 is added or substituted. During phase φ₂, power consumption is a concern because phase φ₂ covers the majority of the frame time. Accordingly, during phase φ₂ the high-ohmic fine string 102 is exercised and the coarse string is substituted by a high-ohmic resistor 127. Generally, a fine resistor unit may be made of several coarse resistor units in parallel to provide good matching.

By using a fraction of the current and a higher-ohmic string in phase φ₂, current and area are saved, as a lower number of parallel units are used in the fine resistor-string 102.

When one of the two coarse resistor-strings 127, 128 is not selected and no current is passing through it, the resistor elements composing the two paths are charged to Vref. When toggling to the next phase, the selected Rcoarse-path settles to its final operating point through a current loop that entails the string, its parasitic capacitances and the local ground, making the transients relatively fast and independent from the reference buffer.

According to embodiments illustrated in FIG. 5A, the fine resistor-string digital-to-analog conversion unit 122 further comprises a low-ohmic fine resistor-string 129 which is connected in parallel to the fine resistor-string 102, a resistance of the low-ohmic fine resistor-string 129 being less than the resistance of the fine resistor-string 102, the low-ohmic fine resistor-string 129 being configured to be connected to the fine multiplexer 108 when the fine multiplexer 108 is connected to the first terminal 137 of the capacitor 111.

Moreover, the coarse resistor-string digital-to-analog conversion unit 121 further comprises a high-ohmic coarse resistor-string 127 which is connected in parallel to the coarse resistor-string 101, a resistance of the high-ohmic coarse resistor-string 127 being greater than the resistance of the coarse resistor-string 101, the coarse resistor-string 127 being configured to be connected to the coarse multiplexer 107 when the coarse multiplexer 107 is connected to the first terminal 137 of the capacitor 111.

The reference buffer may still be operable to regulate fast output current steps. The output stage size and compensation may be adapted to the phase dependent current.

According to embodiments illustrated in FIG. 5A, this may be achieved by disabling certain PMOS transistors on the source-side through PMOS switches, thus keeping all PMOS elements biased and allowing a fast recovery through the low-ohmic on-resistance of the switch.

FIG. 5B shows further embodiments according to which it is possible to mitigate the capacitor droop. As is shown, the DAC 100 further comprises an additional resistor-string 135 comprising switches which may be selectively switched on or off. Due to this additional resistor-string 135, it is possible to compensate the capacitor droop. An extended range for the fine voltage may be achieved. A sub-LSB resolution may be achieved. For example, this additional resistor-string 135 may be controlled by means of a digital word which is adjusted dynamically to compensate for droop in the sampling capacitor. A possible operation is the following: during φ₁, the switches of 135 are all closed. During φ₂, a digital word is programmed to compensate the capacitor droop. In this case, positive droop can be compensated.

Another possible operation is the following: during φ₁, a portion of the switches in additional resistor-string 135 are closed. During φ₂, the digital word is programmed to compensate the capacitor droop. In this case, both positive and negative droops can be compensated, by closing a higher or lower number of switches in the additional resistor-string 135.

According to further embodiments, the additional resistor-string 135 may be arranged above the coarse resistor-string 101. During φ₂, the same operation principles described above are valid.

According to further embodiments, the additional resistor-string 135 may be arranged below the fine resistor-string 102. In such embodiments, the additional resistor-string 135 may implement a total resistance equal to one resistor unit of the fine resistor-string 102, enabling a dynamic capacitor droop compensation and sub-LSB resolution over fine DAC voltage during φ₂.

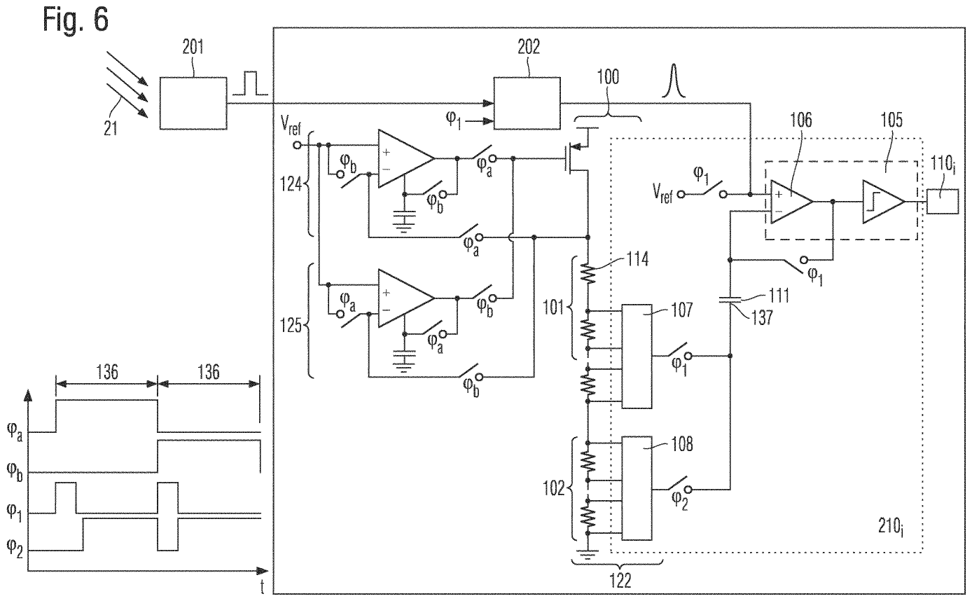

FIG. 6 shows an example of a photon counting system 20, comprising e.g. the DAC 100, which has been described above with reference to FIG. 4C. The photon counting system of FIG. 6 is similar to the photon counting system illustrated in FIG. 1 so that a detailed description of the components will be omitted. Differing from embodiments illustrated in FIG. 1, a single discriminator stage 210ᵢ and further components of the DAC 100 are implemented in a manner as has been described with reference to e.g. FIG. 4C. In more detail, the discriminator 200 which has been described with reference to FIG. 1, comprises a plurality of discriminator stages 210ᵢ that may be implemented in a manner shown in FIG. 6. As is to be clearly understood, the discriminator stages 210ᵢ and the further components of the DAC 100 may also be implemented in any other manner described herein above. The left side of FIG. 6 shows the different phases for operating the discriminator. As is shown, during phase φₐ, a first frame 136 is detected, and the phase φ_{b} corresponds to the second frame 136.

The photon counting system 20 may e.g. be a photon counting CT detector. In such an application X-ray photons are generated externally and are attenuated while traveling through the tissue or an object being analyzed. A photon detector 201 converts each incoming photon 21 into a charge packet which is processed by the CMOS frontend circuit 202. The amplitude of the voltage pulse resulting at the output of the frontend circuit 202 is discretized by means of an array of comparators 105, each being a component of a corresponding one of the discriminator stages 2011. The array of comparators 105 is supplied with an array of threshold voltages that cover the voltage pulse amplitude discretization range.

The discriminator 200 comprises a cluster of n voltage DACs 100, where the coarse resistor-string 101 and the fine resistor-string 102 are shared between all DACs 100. The coarse voltages are stored on the respective capacitors 111 of the comparators 105. As is illustrated, the counting frontend connects to the comparator array either through a switch or directly while making the frontend circuit 102 high-ohmic during phase φ₁.

In CT applications, important to keep the dead time (time when incoming x-ray cannot be used for imaging) low in order to minimize dose exposure to the patient. Offset compensation of the comparator must be completed during this short dead time window, allowing no time for a separate buffer compensation phase. Therefore, as is illustrated in FIG. 6, a ping-pong buffer topology comprising a first buffer circuit 124 and a second buffer circuit 125 may be advantageously employed. Due to this concept, an idle buffer circuit 124, 125 may be offset compensated during the full frame time while still providing an operational path by the other buffer.

As has been explained, due to this figuration, the photon counting system may be employed in medical applications.

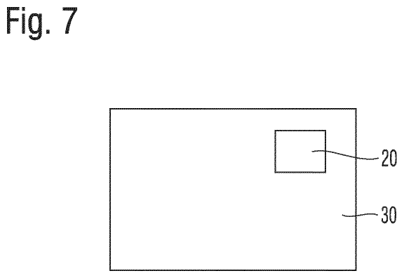

FIG. 7 shows a device for medical diagnosis 30 comprising the photon counting system 20 described hereinabove.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

### LIST OF REFERENCES

20 Photon counting system
21 photons
30 device for medical diagnostics
100, 100₁, 100₂, . . . 100ₙ digital-to-Analog converter
101 coarse resistor-string
102 fine resistor-string
103 bit string
104 switch
105, 105₁, 105₂, . . . 105ₙ comparator
106 preamplifier
107 coarse multiplexer
108 fine multiplexer
109 combining unit
110, 110₁, 110₂, . . . 110ₙ counter
111 capacitor
112 first buffer
113 second buffer
114 resistor
115 circuit arrangement
116 voltage-current-converter
117 baseline control circuit
118 control circuit
119 first buffer capacitor
120 second buffer capacitor
121 coarse resistor-string digital-to-analog conversion unit
122 fine resistor-string digital-to-analog conversion unit
123 switch
124 first buffer circuit
125 second buffer circuit
126 switch
127 high-ohmic coarse resistor-string
129 low-ohmic fine resistor-string
131 amplifier
134 transistor
135 additional resistor-string
136 frame
137 first terminal of capacitor
200 discriminator
201 photon detector
202 frontend circuit
210₁, 210₂, . . . 210ₙ discriminator stage

1. A circuit arrangement comprising a digital-to-analog converter, DAC, and a comparator, the DAC comprising:
a coarse resistor-string digital-to-analog conversion unit for selectively outputting 2^{N}-level analog voltages in response to upper N-bit digital data, wherein N is a natural number greater than or equal to 2;
a fine resistor-string digital-to-analog conversion unit for selectively outputting 2^{N}-level analog voltages in response to lower N-bit digital data, and
a combining unit for combining an output of the coarse resistor-string digital-to-analog conversion unit and the output of the fine resistor-string digital-to-analog conversion unit, the combining unit comprising a capacitor,
the output of the fine resistor-string digital-to-analog conversion unit being connectable to a first terminal of the capacitor, a second terminal of the capacitor being connected to a first input of the comparator, and
the output of the coarse resistor-string digital-to-analog conversion unit is connectable to the first terminal of the capacitor.

2. (canceled)

3. (canceled)

4. (canceled)

5. The circuit arrangement according to claim 1, further comprising a frontend circuit configured to receive an input signal and to supply a processed signal to a second input of the comparator, the frontend circuit being permanently connected to the second input of the comparator, and the processed signal is generated on the basis of the input signal and the output of the coarse resistor-string digital-to-analog conversion unit.

6. A discriminator comprising a plurality of discriminator stages for comparing an input signal with multiple thresholds, each of the discriminator stages comprising
a comparator,
a coarse multiplexer being connectable to a selected tap between resistors of a coarse resistor-string for selectively outputting 2^{N}-level analog voltages in response to upper N-bit digital data, wherein N is a natural number greater than or equal to 2;
a fine multiplexer being connectable to a selected tap between resistors of a fine resistor-string for selectively outputting 2^{N}-level analog voltages in response to lower N-bit digital data, and
a combining unit for combining an output of the coarse multiplexer and the output of the fine multiplexer, the combining unit comprising a capacitor,
the output of the fine multiplexer being connectable to a first terminal of the capacitor, a second terminal of the capacitor being connected to a first input of the comparator.

7. The discriminator according to claim 6, wherein the output of the coarse multiplexer is connectable to a second input of the comparator.

8. The discriminator according to claim 6, wherein the output of the coarse multiplexer is connectable to a frontend circuit configured to receive an input signal and to supply a processed signal to a second input of the comparator, the processed signal being based on the input signal and the output of the coarse multiplexer.

9. (canceled)

10. (canceled)

11. A Digital-to-Analog Converter, DAC, comprising:
a coarse resistor-string digital-to-analog conversion unit for selectively outputting 2^{N}-level analog voltages in response to upper N-bit digital data, wherein N is a natural number greater than or equal to 2;
a fine resistor-string digital-to-analog conversion unit for selectively outputting 2^{N}-level analog voltages in response to lower N-bit digital data, and
a combining unit for combining an output of the coarse resistor-string digital-to-analog conversion unit and the output of the fine resistor-string digital-to-analog conversion unit, the combining unit comprising a capacitor, the output of the coarse resistor-string digital-to-analog conversion unit and the output of the fine resistor-string digital-to-analog conversion unit being connectable to a first terminal of the capacitor, wherein the coarse resistor-string digital-to-analog conversion unit comprises a coarse resistor-string and a coarse multiplexer configured to be connected to a selected tap between resistors of the coarse resistor-string, and
the fine resistor-string digital-to-analog conversion unit comprises a fine resistor-string and a fine multiplexer configured to be connected to a selected tap between resistors of the fine resistor-string, the coarse resistor-string and the fine resistor-string being connected in series.

12. The DAC according to claim 11, further comprising a first buffer receiving a reference voltage and controlling a voltage supplied to the coarse resistor-string.

13. The DAC according to claim 12, wherein the first buffer comprises a first buffer capacitor for storing an offset voltage.

14. The DAC according to claim 13, wherein the first buffer further comprises a second buffer capacitor for storing a reference voltage.

15. The DAC according to claim 13, wherein first buffer comprises a first buffer circuit and a second buffer circuit, each of the first and the second buffer circuits comprising a first buffer capacitor, respectively, the first buffer circuit and the second buffer circuit being configured to be alternatingly operated.

16. The DAC according to claim 11, wherein the coarse resistor-string digital-to-analog conversion unit further comprises a high-ohmic coarse resistor-string which is connected in parallel to the coarse resistor-string, a resistance of the high-ohmic coarse resistor-string being greater than the resistance of the coarse resistor-string, the high-ohmic coarse resistor-string being configured to be connected to the coarse multiplexer when the coarse multiplexer is connected to the first terminal of the capacitor.

17. The DAC according to claim 11, wherein the fine resistor-string digital-to-analog conversion unit further comprises a low-ohmic fine resistor-string which is connected in parallel to the fine resistor-string, a resistance of the low-ohmic fine resistor-string being less than the resistance of the fine resistor-string, the low-ohmic fine resistor-string being configured to be connected to the fine multiplexer when the fine multiplexer is connected to the first terminal of the capacitor.

18. The DAC according to claim 11, further comprising an additional switchable resistor-string between the coarse resistor-string and the fine resistor-string.

19. The circuit arrangement according to claim 1, wherein the output of the fine resistor-string digital-to-analog conversion unit is connected to the first terminal of the capacitor during a phase φ₂, and the coarse resistor-string digital-to-analog conversion unit is connected to the first terminal of the capacitor during a phase φ₁ different from phase φ₂.
